(19) United States
(12) Patent Application Publication
(10) Pub. No.: US 2019/0206904 A1
(43) Pub. Date: Jul. 4, 2019

(54) THIN FILM TRANSISTOR AND METHOD OF MAKING THE SAME, AND ARRAY SUBSTRATE

(71) Applicant: SHENZHEN CHINA STAR OPTOELECTRONICS SEMICONDUCTOR DISPLAY TECHNOLOGY CO., LTD., Shenzhen (CN)

(72) Inventors: Zhichao ZHOU, Shenzhen (CN); Hui XIA, Shenzhen (CN); Meng CHEN, Shenzhen (CN)

(21) Appl. No.: 16/006,685

(22) Filed: Jun. 12, 2018

Related U.S. Application Data
(63) Continuation of application No. PCT/CN2018/073094, filed on Jan. 17, 2018.

(30) Foreign Application Priority Data
Dec. 28, 2017 (CN) 201711463670.7

(51) Int. Cl. H01L 27/12; H01L 29/786; H01L 29/423; H01L 29/66

(52) U.S. Cl. CPC H01L 27/1222; H01L 29/66969; H01L 29/42356; H01L 29/7869

(57) ABSTRACT

A thin film transistor is provided, including a base substrate, a semiconductor active layer, a gate electrode, a gate insulating layer, a source electrode and a drain electrode. The gate insulating layer is formed on the base substrate, the gate insulating layer is provided with a through hole and an annular groove surrounding the through hole. The gate electrode is formed in the through hole, the semiconductor active layer is formed in the annular groove, a height of the gate electrode in the through hole is at least higher than a bottom of the annular groove. The source electrode and the drain electrode are formed on the gate insulating layer at intervals and connected to the semiconductor active layer, respectively. A method of manufacturing the thin film transistor and an array substrate including the thin film transistor are also provided.

### RELATED APPLICATIONS

The present application is a National Phase of International Application Number PCT/CN2018/073094, filed Jan. 17, 2018, and claims the priority of China Application 201711463670.7, filed Dec. 28, 2017.

### FIELD OF THE DISCLOSURE

The disclosure relates to a semiconductor device technical field, and more particularly to a thin film transistor and a method of making the same, and further relates to an array substrate comprising the thin film transistor.

### BACKGROUND

Flat panel display with thin body, power saving, no radiation and many other advantages, has been widely used. The existing flat panel display devices mainly include a liquid crystal display (LCD) and an organic light emitting display (OLED). Thin film transistor (TFT) array substrate is an important part of a flat panel display device and can be formed on a glass substrate or a plastic substrate.

In the conventional technology, as shown in FIG. 1, the thin film transistor includes a gate electrode 2 formed on a glass substrate 1, a gate insulating layer 3 overlying the gate electrode 2, an active layer 4 formed over the gate insulating layer 3, and a source electrode 5 and a drain electrode 6 formed on the active layer 4. The source electrode 5 and the drain electrode 6 are spaced apart from each other, and a region corresponding to the gate electrode 2 of the active layer 4 is a channel region 4a. In the thin film transistor structure as shown in FIG. 1, the active layer 4 is exposed to the gate insulating layer 3, the channel region 4a of the active layer 4 is easily affected by the subsequent steps. In particular, when the active layer is using an oxide semiconductor material. For example, in the mask process of forming the source electrode 5 and the drain electrode 6 after the active layer 4 is formed, the surface of the channel region of the active layer 4 is easily damaged by the etchant to cause the electrical characteristics of the thin film transistor (such as reliability and stability of threshold voltage) deteriorate.

### SUMMARY

Accordingly, the present disclosure provides a thin film transistor and a method of making the same, which can protect the channel region of the thin film transistor effectively, and improve the stability of the electrical characteristics of the thin film transistor.

In order to achieve the above objectives, the present disclosure adopts the technical solution as follows:

A thin film transistor comprises a base substrate, a semiconductor active layer, a gate electrode, a gate insulating layer, a source electrode and a drain electrode. Herein, the gate insulating layer is formed on the base substrate, a through hole and an annular groove surrounding the through hole are provided in the gate insulating layer, the gate electrode is formed in the through hole, the semiconductor active layer is formed in the annular groove, a height of the gate electrode in the through hole is at least higher than a bottom of the annular groove, the source electrode and the drain electrode are formed on the gate insulating layer at intervals and electrically connected to the semiconductor active layer, respectively.

Herein, the thin film transistor further comprises a gate base formed on the base substrate, the gate insulating layer is located on the gate base, the through hole connects to the gate base, and the gate electrode is formed in the through hole and connected with the gate base.

Herein, the gate base comprises a first region connected with the gate electrode and a second region extended from two opposite sides of the first region, a line width of the first region is greater than a line width of the second region.

Herein a height of the gate electrode is at least flush with an upper surface of the gate insulating layer.

Herein, the through hole is a circular through hole, the annular groove is a circle annular groove, and the through hole and the annular groove are coaxial structures.

Herein, a material of the semiconductor active layer is an oxide semiconductor material.

Herein, the source electrode and the drain electrode are located at opposite sides of the gate electrode on the gate insulating layer, a position of the semiconductor active layer where the source electrode and the drain electrode are connected is conductorized to form a conductor.

The present disclosure further provides a method of manufacturing the foregoing thin film transistor, comprising:

providing a base substrate, and deposing a gate insulating layer on the base substrate; etching the gate insulating layer to form an annular groove by using photomask process;

depositing a semiconductor material in the annular groove to form a semiconductor active layer,

etching a region of the gate insulating layer surrounded by the annular groove to form a through hole by using photomask process;

depositing a metal material in the through hole and on the gate insulating layer simultaneously to form a gate electrode, a source electrode and a drain electrode.

Herein, before depositing and forming the gate insulating layer, firstly, a gate base is formed on the base substrate by using a mask process; wherein the through hole is connected to the gate base, the gate electrode and the gate base are interconnected.

Another aspect of the present disclosure is to provide an array substrate, comprising the foregoing thin film transistor.

Among the thin film transistor and the method of making in the embodiments provided by the present disclosure, the semiconductor active layer is embedded in the gate insulating layer. The semiconductor active layer is surrounded around the gate electrode to form a vertical structured channel region, the surface of the channel region is covered and protected by the gate insulating layer. Therefore, adverse effects on the channel region caused by the subsequent process after the semiconductor active layer is formed can be effectively avoided, and the stability of the electrical characteristics of the thin film transistor can be improved.

### BRIEF DESCRIPTION OF THE DRAWINGS

FIG. 1 is a schematic cross-sectional structure of a conventional thin film transistor;

FIG. 2 is a schematic plan view of a thin film transistor provided in Embodiment 1 of the present disclosure;

FIG. 3 is a schematic cross-sectional structure of a thin film transistor provided in Embodiment 1 of the present disclosure;

FIG. 4a to FIG. 4i are exemplary structural diagrams of the device obtained in each step of manufacturing a thin film transistor according to Embodiment 1 of the present disclosure;

FIG. 5 is a structural schematic view of an array substrate in Embodiment 2 of the present disclosure.

### DETAILED DESCRIPTION OF PREFERRED EMBODIMENTS

In order to understand the above objectives, features and advantages of the present disclosure more clearly, the present disclosure is described in detail below with references to the accompanying drawings and specific embodiments. The embodiments of the present disclosure shown in the drawings and described in the drawings are merely exemplary and the present disclosure is not limited to these embodiments.

Herein, it should also be noted that in order to avoid obscuring the present disclosure with unnecessary detail, only the structures and/or processing steps that are closely related to the solution according to the present disclosure are shown in the drawings, other details are of little relevance.

### Embodiment 1

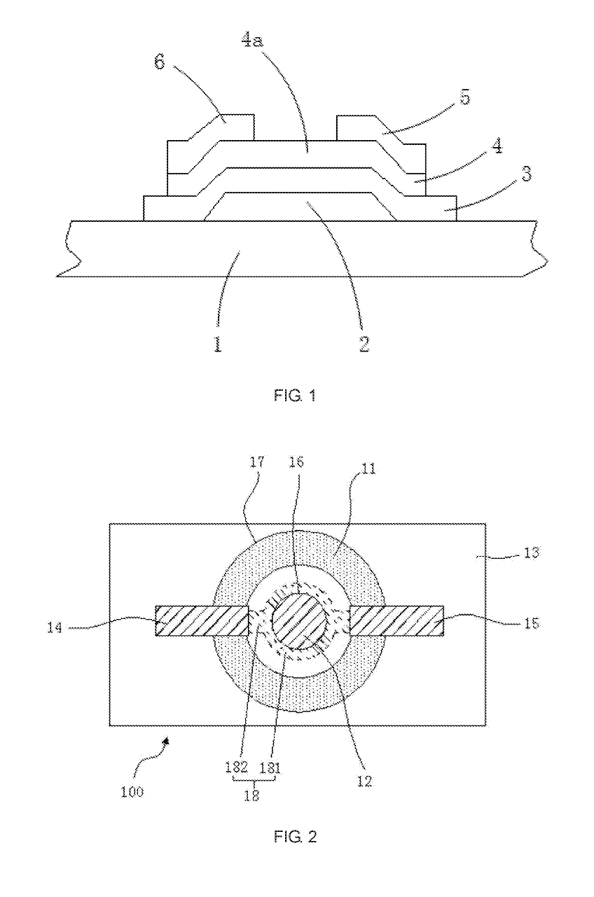

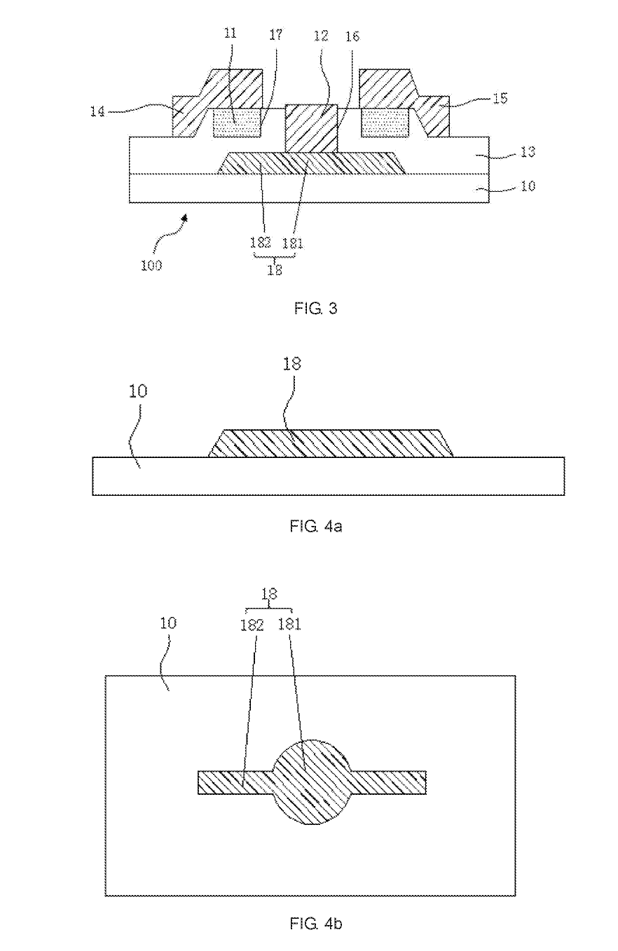

The present disclosure provides a thin film transistor 100. Please refer to FIG. 2 and FIG. 3, the thin film transistor comprises a semiconductor active layer 11, a gate electrode 12, a gate insulating layer 13, a source electrode 14 and a drain electrode 15 formed on a base substrate 10. The gate insulating layer 13 is formed on the base substrate 10, a through hole 16 and an annular groove 17 surrounding the through hole 16 are provided in the gate insulating layer 13, the gate electrode 12 is formed in the through hole 16, the semiconductor active layer 11 is formed in the annular groove 17. The source electrode 14 and the drain electrode 15 are formed on the gate insulating layer 13 at intervals and connected to the semiconductor active layer 11, respectively.

Herein, a height of the gate electrode 12 in the through hole 16 is at least higher than a bottom of the annular groove 17, so that the sidewall of the gate electrode 12 and the sidewall of the semiconductor active layer 11 have overlapping portions with each other, and are separated from each other by the gate insulating layer 13. In one embodiment, the height of the gate electrode 12 is at least flush with an upper surface of the gate insulating layer 13. As shown in FIG. 3, the gate electrode 12 in the through hole 16 is slightly protruded from the upper surface of the gate insulating layer 13, so as to ensure that the overlapping portion of the sidewalls of the gate electrode 12 and the side wall of the semiconductor active layer 11 is maximized.

Furthermore, in the present embodiment, as shown in FIG. 2 and FIG. 3, the thin film transistor 100 further comprises a gate base 18 formed on the base substrate 10, the gate insulating layer 13 is located on the gate base 18, the through hole 16 is connected to the gate base 18, and the gate electrode 12 is formed in the through hole 16 and connected with the gate base 18. Herein, the gate base 18 may be regarded as a connection lead of the gate electrode 12. In addition, it should be noted that the dotted line in FIG. 2 indicates a perspective view of the gate base 18 under the gate insulating layer 13.

The thin film transistor 100 as described above, the semiconductor active layer 11 is formed in the annular groove 17. That is, the semiconductor active layer 11 is embedded in the gate insulating layer 13, and the semiconductor active layer 11 is surrounded around the gate electrode 12 to form a vertical structured channel region, the surface of the channel region is covered and protected by the gate insulating layer 13. Therefore, adverse effects on the channel region caused by the subsequent process after the semiconductor active layer 11 is formed can be effectively avoided, and the stability of the electrical characteristics of the thin film transistor can be improved.

In the present disclosure, please refer to FIG. 2, the gate base 18 comprises a first region 181 connected with the gate electrode 12 and a second region 182 extended from two opposite sides of the first region 181. A line width of the first region 181 is greater than a line width of the second region 182, so as to enable the gate electrode 12 to be electrically connected to the gate base 18. Further, the first region 181 is preferably larger than the cross-sectional area of the gate electrode 12 so that the gate electrode 12 completely falls within the first region 181.

In the present disclosure, please refer to FIG. 2, the through hole 16 is a circular through hole, the gate electrode 12 formed in the through hole 16 is a cylindrical structure. The annular groove 17 is a circle annular groove, the semiconductor active layer 11 formed in the annular groove 17 is also a circle structure, and the source electrode 14 and the drain electrode 15 are located at opposite sides of the gate electrode 12 on the gate insulating layer 13. Besides, preferably, the through hole 16 and the annular groove 17 are coaxial structures. It should be noted that, in some embodiments, the through hole 16 and the annular groove 17 can also be other shape structures. For example, the through hole 16 can be provided as a square through hole, and the annular groove 17 can be provided as a squared annular groove, only needs to meet the annular groove 17 around the through hole 16, so as to correspondingly surround the semiconductor active layer 11 around the gate electrode 12 to form a vertical structured channel region.

In this embodiment, a material of the semiconductor active layer 11 is selected as an oxide semiconductor material, and a position of the semiconductor active layer 11 where the source electrode 14 and the drain electrode 15 are connected is conductorized to form a conductor. It should be noted that in other embodiments, the material of the semiconductor active layer 11 may also be selected from other commonly used semiconductor materials in the art, such as amorphous silicon or polysilicon, and so on.

Herein, in the present embodiment, the oxide semiconductor material can be GaInZnO. In some embodiments, the oxide semiconductor material can be further selected from ZnO, InZnO, ZnSnO and ZrInZnO.

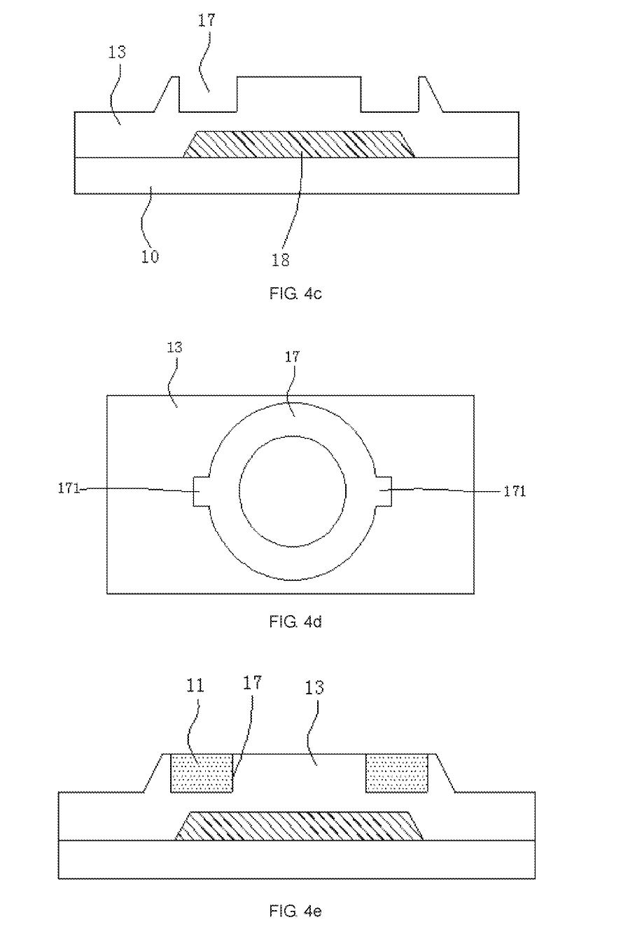

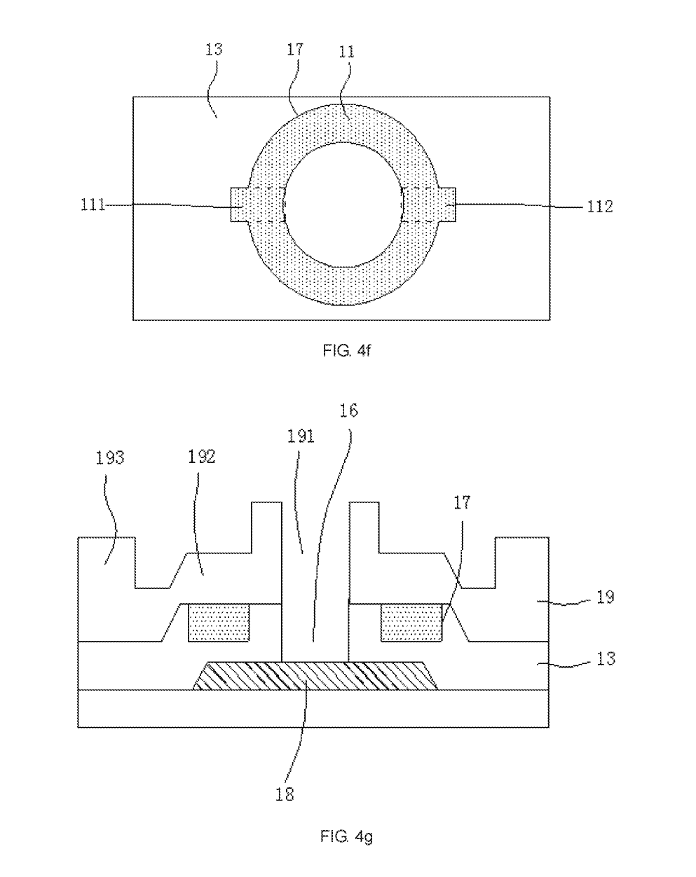

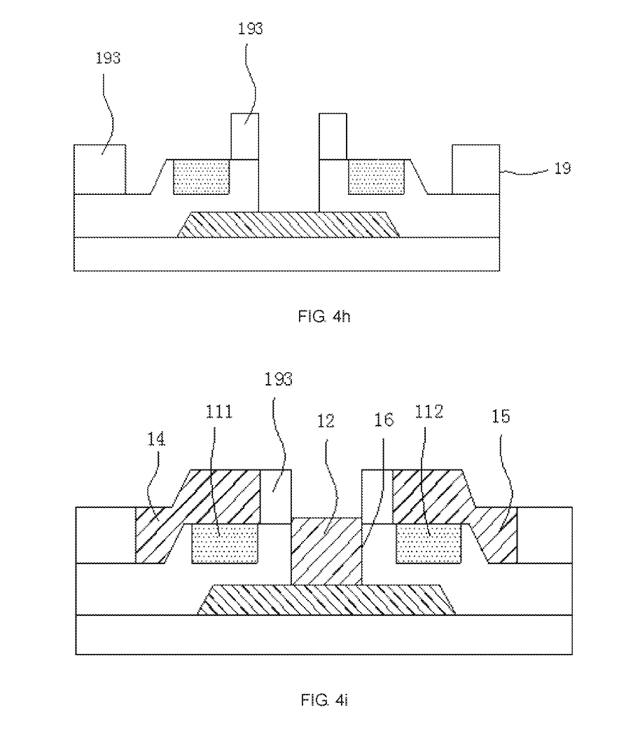

The present embodiment further provides a method of manufacturing the thin film transistor as described above. Referring to FIG. 4a to FIG. 4i, with the process of the preparation method will be described with reference to FIGS. 2 and 3. The method for manufacturing the thin film transistor comprises the following steps:

S10, referring to FIGS. 4a and 4b. Providing a base substrate 10 by adopting first photomask process (patterning process), and preparing a patterned gate base 18 on the base substrate 10. Wherein, FIG. 4b is a schematic plan view corresponding to FIG. 4a. As shown in FIG. 4b, the gate base 18 comprises a first region 181 and a second region 182 extended from two opposite sides of the first region 181. The line width of the first region 181 is greater than the line width of the second region 182, and the first region 181 is for interconnection with a subsequently formed gate electrode.

S20, referring to FIGS. 4c and 4d. Deposing a gate insulating layer 13 on the base substrate 10, the gate insulating layer 13 covers the gate base 18. And then etching the gate insulating layer 13 to form an annular groove 17 by adopting second photomask process. Herein, FIG. 4d is a schematic plan view corresponding to FIG. 4c. As shown in FIG. 4d, two opposite sides of the annular groove 17 have protrusions 171, the protrusions 171 are corresponding to a position for the source electrode and the drain electrode to be subsequently connected. By providing the protrusions 171, it is possible to increase the contact area of the active semiconductor layer with the source and drain electrodes formed in the annular groove 17, resulting in better electrical connection performance.

S30, referring to FIGS. 4e and 4f. Depositing a semiconductor material in the annular groove 17 to form a semiconductor active layer 11. Particularly, a photoresist mask can be provided as only exposing the annular groove 17 on the gate insulating layer 13, and then a semiconductor material is deposited. Finally, the photoresist mask is stripped to obtain a the semiconductor active layer 11 in the annular groove 17.

Herein, FIG. 4f is a schematic plan view corresponding to FIG. 4e. As shown in FIG. 4e and FIG. 4f, the semiconductor active layer 11 is embedded in the gate insulating layer 13. Further, in the present embodiment, the material of the semiconductor active layer 11 is an oxide semiconductor material. After the semiconductor active layer 11 is deposited, the source region 111 needs to be connected to the source electrode and the drain region 112 needs to be connected to the drain electrode conduct the semiconductor active layer 11. Specifically, a mask can be provided only exposing the source region 111 and the drain region 112 on the semiconductor active layer 11, and then the oxide semiconductor material of the source region 111 and the drain region 112 is converted into a conductor by applying an ion implantation process, a plasma bombardment process or a UV light irradiation process.

S40, referring to FIG. 4g. Etching a region of the gate insulating layer 13 surrounded by the annular groove to form a through hole 16 by using third photomask process.

Specifically, as shown in FIG. 4g, during the third photomask process, a photoresist mask 19 is formed on the gate insulating layer 13. The photoresist mask 19 is exposed by using a half-tone exposure method. An exposed region 191, a first thickness region 192 and the second thickness region 193 are formed after the exposure. The pattern of the exposed region 191 corresponds to a pattern that needs to be etched to form the through hole 16. The thickness of the first thickness region 192 is less than the thickness of the second thickness region 193. The pattern of the first thickness region 192 corresponds to a pattern of the source and drain electrodes to be formed subsequently.

After forming the photoresist mask 19 by exposure and development, the gate insulating layer 13 is etched from the exposed region 191 to obtain a through hole 16 connecting to the gate base 18, and the through hole 16 is connecting to the first region 181 of the gate base 18.

S50, referring to FIG. 4h and FIG. 4i. Depositing a metal material in the through hole 16 and on the gate insulating layer 13 simultaneously to form a gate electrode 12, a source electrode 14 and a drain electrode 15.

First, as shown in FIG. 4h, the photoresist mask 19 formed in step S40 is subjected to an ashing process to completely remove the photoresist in the first thickness region 192 and thin the photoresist in the second thickness region 193.

And then, as shown in FIG. 4i, a metal material for forming an electrode is deposited under the protection of a photoresist in the second thickness region 193. The metal material is deposited in the through hole 16 to form the gate electrode 12. The metal material is deposited on the gate insulating layer 13 and on the source region 111 and drain region 112 of the semiconductor active layer 11 (the pattern corresponding to the aforementioned first thickness region 192), and respectively forming the source electrode 14 and the drain electrode 15 which connect to the semiconductor active layer 11.

Finally, the photoresist mask 19 is peeled off to obtain a thin film transistor as shown in FIG. 2 and FIG. 3.

According to the method of manufacturing a thin film transistor provided by the above embodiment, since the semiconductor active layer 11 is embedded in the gate insulating layer 13, the semiconductor active layer 11 is provided around the gate electrode 12 to form a vertical structured channel region. The surface of the channel region is covered and protected by the gate insulating layer 13. Therefore, the adverse effects on the channel region of the semiconductor active layer 11 by subsequent processes (such as the patterning process for preparing the source electrode 14 and the drain electrode 15) after preparing the semiconductor active layer 11 are small, the prepared thin film transistor has excellent electrical characteristics.

### Embodiment 2

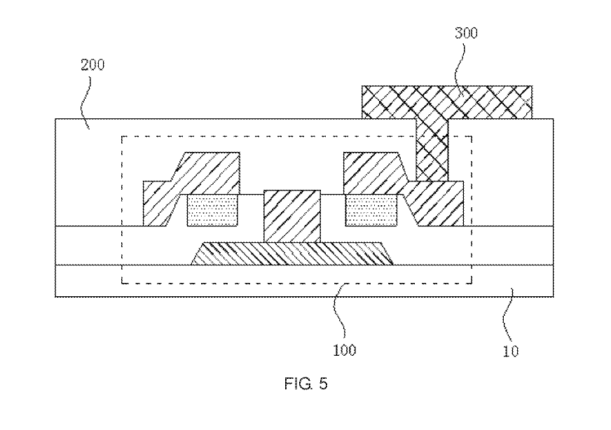

The present embodiment provides an array substrate. As shown in FIG. 5, the array substrate comprises a plurality of thin film transistors 100 arranged in array on a base substrate 1. The thin film transistors 100 are the thin film transistors described in Embodiment 1 of the present disclosure, wherein only one of the thin film transistors 100 is exemplarily shown in FIG. 5. A passivation layer 200 is further disposed on the thin film transistor 100, a pattered pixel electrode 300 is formed on the passivation layer 200, and the pixel electrode 300 is electrically connected to the thin film transistor 100 via a through hole in the passivation layer 200.

The array substrate provided by the present disclosure is prepared by the steps of:

S100, preparing thin film transistors 100 arranged in array on the base substrate 1. Specifically, the thin film transistors 100 are formed on the base substrate 10 by adopting the manufacturing method as described in Embodiment 1.

S200, preparing a passivation layer 200 on the thin film transistor 100, and etching the passivation layer 200 to form a through hole by applying photomask process.

S300, preparing a patterned pixel electrode 300 on the passivation layer 200 by using a photomask process. The pixel electrode 300 is electrically connected to the thin film transistor 100 (to the source electrode or the drain electrode of the thin film transistor) via the through hole in the passivation layer 200.

In summary, among the thin film transistor and the method of manufacturing the thin film transistor provided in the embodiments of the present disclosure, the semiconductor active layer is embedded in the gate insulating layer to form a vertical structured channel region, which can effectively protect the channel region of the thin film transistor, and improve the stability of the electrical characteristics of the thin film transistor.

It should be noted that, in this document, relational terms such as first and second are merely used to distinguish one entity or operation from another entity or operation, and do not necessarily require or imply that there is any such actual relationship or order between the entity and operation. Moreover, the terms “include”, “comprise” or any other variations thereof are intended to cover a non-exclusive inclusion, such that a process, method, article, or device includes not only those elements but also other elements that are inherent to such process, method, article, or device. Without further limitations, an element limited by the statement “comprising a . . . ” does not exclude the existence of additional identical elements in the process, method, article, or device.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A thin film transistor comprising a base substrate, a semiconductor active layer, a gate electrode, a gate insulating layer, a source electrode and a drain electrode, wherein the gate insulating layer is formed on the base substrate, a through hole and an annular groove surrounding the through hole are provided in the gate insulating layer, the gate electrode is formed in the through hole, the semiconductor active layer is formed in the annular groove, a height of the gate electrode in the through hole is at least higher than a bottom of the annular groove, the source electrode and the drain electrode are formed on the gate insulating layer at intervals and electrically connected to the semiconductor active layer, respectively.

2. The thin film transistor according to claim 1, wherein the thin film transistor further comprises a gate base formed on the base substrate, the gate insulating layer is located on the gate base, the through hole connects to the gate base, and the gate electrode is formed in the through hole and connected with the gate base.

3. The thin film transistor according to claim 2, wherein the gate base comprises a first region connected with the gate electrode and a second region extended from two opposite sides of the first region, a line width of the first region is greater than a line width of the second region.

4. The thin film transistor according to claim 1, wherein a height of the gate electrode is at least flush with an upper surface of the gate insulating layer.

5. The thin film transistor according to claim 1, wherein the through hole is a circular through hole, the annular groove is a circle annular groove, and the through hole and the annular groove are coaxial structures.

6. The thin film transistor according to claim 1, wherein a material of the semiconductor active layer is an oxide semiconductor material.

7. The thin film transistor according to claim 6, wherein the source electrode and the drain electrode are located at opposite sides of the gate electrode on the gate insulating layer, a position of the semiconductor active layer where the source electrode and the drain electrode are connected is conductorized to form a conductor.

8. A method of manufacturing a thin film transistor, comprising:
providing a base substrate, and deposing a gate insulating layer on the base substrate;
etching the gate insulating layer to form an annular groove by using a second photomask process;
depositing a semiconductor material in the annular groove to form a semiconductor active layer;
etching a region of the gate insulating layer surrounded by the annular groove to form a through hole by using a third photomask process; and
depositing a metal material in the through hole and on the gate insulating layer simultaneously to form a gate electrode, a source electrode and a drain electrode;
wherein the gate electrode is formed in the through hole, a height of the gate electrode in the through hole is at least higher than a bottom of the annular groove;
the source electrode and the drain electrode are formed on the gate insulating layer at intervals and connected to the semiconductor active layer, respectively.

9. The method of manufacturing a thin film transistor according to claim 8, wherein before depositing the gate insulating layer, a gate base is first prepared on the base substrate by a first photomask process; and wherein the through hole connects to the gate base, the gate electrode and the gate base are connected with each other.

10. The method of manufacturing a thin film transistor according to claim 9, wherein the gate base comprises a first region connected with the gate electrode and a second region extended from two opposite sides of the first region, a line width of the first region is greater than a line width of the second region.

11. The method of manufacturing a thin film transistor according to claim 8, wherein a height of the gate electrode is at least flush with an upper surface of the gate insulating layer.

12. The method of manufacturing a thin film transistor according to claim 8, wherein the through hole is a circular through hole, the annular groove is a circle annular groove, and the through hole and the annular groove are coaxial structures.

13. The method of manufacturing the thin film transistor according to claim 8, wherein a material of the semiconductor active layer is an oxide semiconductor material, the source electrode and the drain electrode are located at opposite sides of the gate electrode on the gate insulating layer, a position of the semiconductor active layer where the source electrode and the drain electrode are connected is conductorized to form a conductor.

14. An array substrate comprising a thin film transistor formed on a base substrate, the thin film transistor comprising a semiconductor active layer, a gate electrode, a gate insulating layer, a source electrode, and a drain electrode; wherein the gate insulating layer is formed on the base substrate, a through hole and an annular groove surrounding the through hole are provided in the gate insulating layer, the gate electrode is formed in the through hole, the semiconductor active layer is formed in the annular groove, a height of the gate electrode in the through hole is at least higher than a bottom of the annular groove, the source electrode and the drain electrode are formed on the gate insulating layer at intervals and electrically connected to the semiconductor active layer, respectively.

15. The array substrate according to claim 14, wherein the thin film transistor further comprises a gate base formed on the base substrate, the gate insulating layer is located on the gate base, the through hole connects to the gate base, and the gate electrode is formed in the through hole and connected with the gate base.

16. The array substrate according to claim 15, wherein the gate base comprises a first region connected with the gate electrode and a second region extended from two opposite sides of the first region, a line width of the first region is greater than a line width of the second region.

17. The array substrate according to claim 14, wherein a height of the gate electrode is at least align to an upper surface of the gate insulating layer.

18. The array substrate according to claim 14, wherein the through hole is a circular through hole, the annular groove is a circle annular groove, and the through hole and the annular groove are coaxial structures.

19. The array substrate according to claim 14, wherein a material of the semiconductor active layer is an oxide semiconductor material.

20. The array substrate according to claim 19, wherein the source electrode and the drain electrode are located at opposite sides of the gate electrode on the gate insulating layer, a position of the semiconductor active layer where the source electrode and the drain electrode are connected is conductorized to form a conductor.
